(19) United States
(12) Patent Application Publication
(10) Pub. No.: US 2026/0082590 A1
(43) Pub. Date: Mar. 19, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Atsushi KATAOKA, Chigasaki Kanagawa (JP)

(73) Assignee: Kioxia Corporation, Tokyo (JP)

(21) Appl. No.: 19/059,325

(22) Filed: Feb. 21, 2025

(30) Foreign Application Priority Data
Sep. 19, 2024 (JP) 2024-162425

(51) Int. Cl. H10B 80/00; H01L 25/00; H01L 25/065

(52) U.S. Cl. CPC H10B 80/00; H10W 90/00; H10W 90/24; H10W 90/291; H10W 90/752; H10W 90/754

(57) ABSTRACT

According to one embodiment, a semiconductor device includes a wiring board, a first semiconductor module that includes one or more first semiconductor chips staked together, a wire that connects one of the one or more first semiconductor chips to the wiring board, and a second semiconductor module that is arranged adjacent to the first semiconductor module and includes second semiconductor chips stacked together. At least part of the wire is in contact with an adhesive layer between an N-th second semiconductor chip and an (N+1)th second semiconductor chip from a lowermost layer among the second semiconductor chips.

### CROSS-REFERENCE TO RELATED APPLICATIONS

This application is based upon and claims the benefit of priority from Japanese Patent Application No. 2024-162425, filed on Sep. 19, 2024; the entire contents of which are incorporated herein by reference.

### FIELD

Embodiments described herein relate generally to a semiconductor device and a method of manufacturing the semiconductor device.

### BACKGROUND

For example, there is a semiconductor package in which a plurality of semiconductor modules each of which includes a plurality of memory chips stacked together is mounted on a wiring board by using a wire. The plurality of semiconductor modules may be mounted close to each other in some cases. A wire that extends from one semiconductor module may interfere with an adjacent semiconductor module to cause a short circuit in some cases.

### BRIEF DESCRIPTION OF THE DRAWINGS

FIG. 1 is a top view illustrating a schematic configuration example of a semiconductor device according to an embodiment;

FIGS. 2A and 2B are cross-sectional views illustrating a detailed configuration of the semiconductor device according to the embodiment;

FIGS. 3A to 3C are side views illustrating a detailed configuration of the semiconductor device according to the embodiment;

FIGS. 4A and 4B are diagrams illustrating an example of a procedure of a method of manufacturing the semiconductor device according to the embodiment;

FIGS. 5A and 5B are diagrams illustrating an example of a procedure of the method of manufacturing the semiconductor device according to the embodiment;

FIGS. 6A and 6B are diagrams illustrating an example of a procedure of the method of manufacturing the semiconductor device according to the embodiment;

FIGS. 7A and 7B are diagrams illustrating an example of a procedure of the method of manufacturing the semiconductor device according to the embodiment;

FIGS. 8A and 8B are diagrams illustrating an example of a procedure of the method of manufacturing the semiconductor device according to the embodiment;

FIGS. 9A and 9B are diagrams illustrating an example of a procedure of the method of manufacturing the semiconductor device according to the embodiment;

FIG. 10 is a diagram explaining a semiconductor device according to a first variation of the embodiment;

FIG. 11 is a diagram explaining a semiconductor device according to a second variation of the embodiment;

FIG. 12 is a top view illustrating a schematic configuration example of a semiconductor device according to a third variation of the embodiment; and

FIG. 13 is a cross-sectional view illustrating a detailed configuration of the semiconductor device according to the third variation of the embodiment.

### DETAILED DESCRIPTION

In general, according to one embodiment, a semiconductor device includes: a wiring board; a first semiconductor module that is arranged on a principal surface of the wiring board, and includes one or more first semiconductor chips staked together; a wire that connects one of the one or more first semiconductor chips to the wiring board; and a second semiconductor module that is arranged on the principal surface of the wiring board to be adjacent to the first semiconductor module, and includes a plurality of second semiconductor chips stacked together. The second semiconductor module includes an adhesive layer between an N-th second semiconductor chip (N is an integer of 1 or more) and an (N+1)th second semiconductor chip from a lowermost layer among the plurality of second semiconductor chips, and at least part of the wire is in contact with the adhesive layer.

Exemplary embodiments of a semiconductor device and a method of manufacturing the semiconductor device will be explained below in detail with reference to the accompanying drawings. The present invention is not limited to the following embodiments.

### Configuration Example of Semiconductor Device

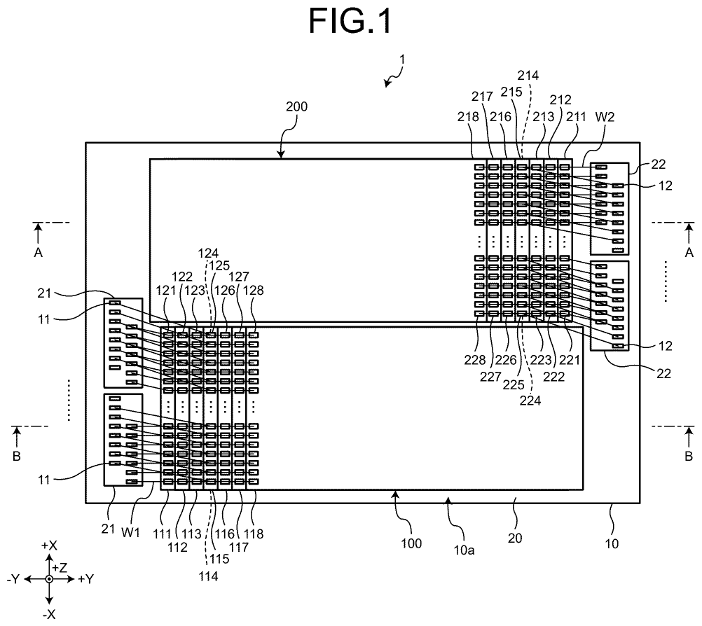

FIG. 1 is a top view illustrating a schematic configuration example of a semiconductor device 1 according to an embodiment. In FIG. 1, illustration of some configurations such as a sealing member is omitted.

Herein, it is assumed that, when viewed from a wiring board 10, a side on which a first semiconductor module 100 and a second semiconductor module 200 have been mounted is an upper side, a side of the wiring board 10 is a lower side, and an upward/downward direction is a Z direction. Both an X direction and a Y direction are directions along an orientation of a plane of the wiring board 10, and the X direction and the Y direction are directions orthogonal to each other. The X direction is an example of a third direction. It is also assumed that a side pointed by an arrow of each axis is a positive direction, and an opposite side is a negative direction. A positive Y direction is an example of a first direction, and a negative Y direction is an example of a second direction. Furthermore, a positive Z direction is an example of a stacked direction.

As illustrated in FIG. 1, the semiconductor device 1 is configured as a package in which a plurality of semiconductor chips has been sealed. The semiconductor device 1 includes the wiring board 10, the first semiconductor module 100, the second semiconductor module 200, and wires W1 and W2.

On an upper surface 10a serving as a principal surface of the wiring board 10, the first semiconductor module 100 and the second semiconductor module 200 are arranged in the X direction. Each of the first semiconductor module 100 and the second semiconductor module 200 has a configuration in which a plurality of semiconductor chips has been stacked. The semiconductor chip is a small piece obtained by segmenting an Si substrate or the like, and, for example, a not-illustrated semiconductor element is incorporated into the semiconductor chip. The semiconductor element is a non-volatile memory such as a NAND flash memory.

Furthermore, when viewed in the Z direction, at both ends in the Y direction that are located outside the first semiconductor module 100 and the second semiconductor module 200 in the wiring board 10, a plurality of electrodes 11 and a plurality of electrodes 12 that each are arranged in the X direction are respectively arranged. More specifically, the electrodes 11 are arranged in a position closer to a negative X direction side at an end located on a negative Y direction side of the wiring board 10. Furthermore, the electrodes 12 are arranged in a position closer to a positive X direction side at an end located on a positive Y direction side of the wiring board 10. Stated another way, the electrodes 11 are located on the negative Y direction side when viewed from the first semiconductor module 100, and the electrodes 12 are located on the positive Y direction side when viewed from the second semiconductor module 200.

The upper surface 10a of the wiring board 10 is covered with a solder resist 20. The plurality of electrodes 11 and the plurality of electrodes 12 are respectively exposed in an opening 21 and an opening 22 of the solder resist 20.

The first semiconductor module 100 has a configuration in which semiconductor chips 111 to 118 have been stacked to shift in the positive Y direction. Therefore, ends located on the negative Y direction side in upper surfaces of the individual semiconductor chips 111 to 117 respectively have portions that do not overlap the semiconductor chips 112 to 118 located just above. These portions and an end in the negative Y direction of an upper surface of the semiconductor chip 118 in an uppermost layer are respectively provided with a plurality of electrode pads 121 to a plurality of electrode pads 128 that each are arranged in the X direction. The electrode pads 121 to 128 are connected to not-illustrated semiconductor elements that are respectively incorporated into the semiconductor chips 111 to 118. Furthermore, each of the electrode pads 121 to 128 is connected to the wire W1 that extends toward the electrode 11.

The second semiconductor module 200 has a configuration in which semiconductor chips 211 to 218 have been stacked to shift in the negative Y direction. Therefore, ends located on the positive Y direction side in upper surfaces of the individual semiconductor chips 211 to 217 respectively have portions that do not overlap the semiconductor chips 212 to 218 located just above. These portions and an end located on the positive Y direction side in an upper surface of the semiconductor chip 218 in an uppermost layer are respectively provided with a plurality of electrode pads 221 to a plurality of electrode pads 228 that each are arranged in the X direction. Furthermore, each of the electrode pads 221 to 228 is connected to the wire W2 that extends toward the electrode 12.

The wires W1 and W2 contain at least any metal material of, for example, Au, Cu, Pd, Cu, and Ag. The wires W1 and W2 respectively connect the electrode pads 121 to 128 and the electrode pads 221 to 228 that are respectively provided for the first semiconductor module 100 and the second semiconductor module 200 to the electrodes 11 and the electrodes 12. As a result of this, the wiring board 10, the first semiconductor module 100, and the second semiconductor module 200 are electrically connected.

The wiring board 10, the first semiconductor module 100, the second semiconductor module 200, and the wires W1 and W2 are covered with a not-illustrated sealing member.

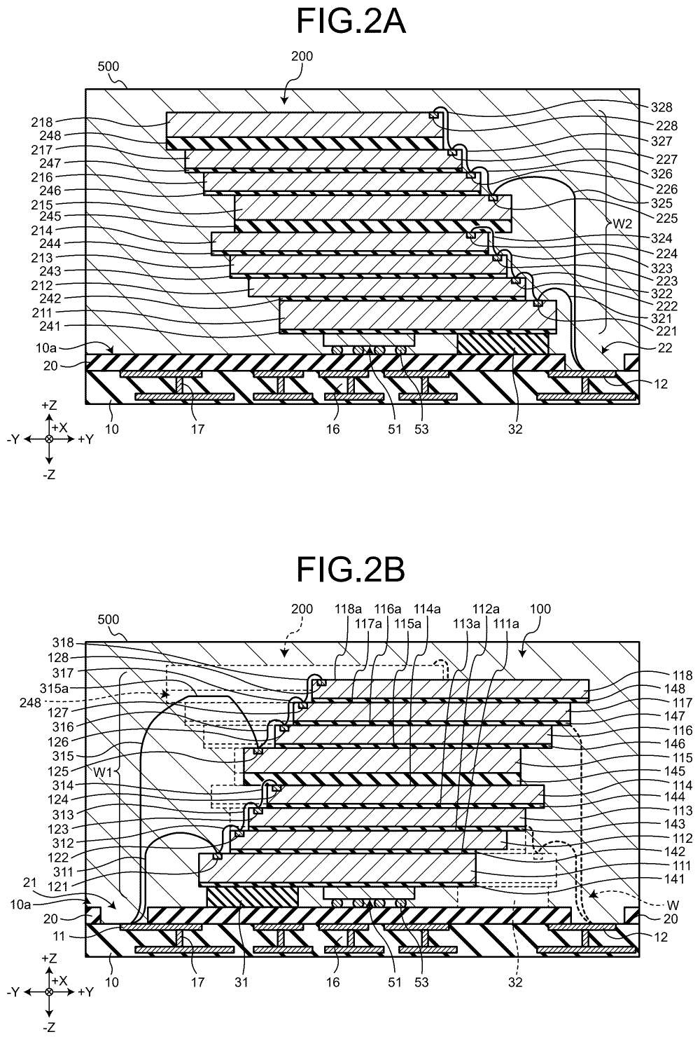

FIGS. 2A and 2B are cross-sectional views illustrating a detailed configuration of the semiconductor device 1 according to the embodiment. More specifically, FIG. 2A is a cross-sectional view taken along line AA of FIG. 1. Stated another way, FIG. 2A is a cross-sectional view of the semiconductor device 1 including the second semiconductor module 200. Furthermore, FIG. 2B is a diagram illustrating a cross section taken along line BB of FIG. 1 that has been superimposed onto a cross section taken along line AA of FIG. 1. Stated another way, FIG. 2B is a diagram in which a cross-sectional view of the semiconductor device 1 including the first semiconductor module 100 has been superimposed onto a cross-sectional view of the semiconductor device 1 including the second semiconductor module 200. Note that, in consideration of easiness of view, in FIG. 2B, a configuration included in the second semiconductor module 200 is illustrated with a broken line, and hatching is partially omitted in some cases.

As illustrated in FIGS. 2A and 2B, the wiring board 10 is configured as a multilayer board in which an insulating layer 16 and a conductive layer 17 have been alternately stacked plural times. Furthermore, the wiring board 10 includes the electrodes 11 and the electrodes 12.

The insulating layer 16 is made of a carbon fiber that has been impregnated with a thermosetting resin such as an epoxy resin before curing, a glass fiber, an aramid fiber, or the like.

The conductive layer 17, and the electrode 11 and the electrode 12 are made of metal such as Cu. The conductive layer 17 has a wiring pattern, and is connected to each of the electrodes 11 and the electrodes 12. A not-illustrated electrode that is arranged on a lower surface of the wiring board 10 is electrically connected to an external power supply of a host computer or the like via a mother board or the like.

On the upper surface 10a of the wiring board 10, a spacer 31 and a spacer 32 are provided. The spacer 31 and the spacer 32 are small pieces of the Si substrate or the like. The spacer 31 supports the first semiconductor module 100 on the upper surface, and the spacer 32 supports the second semiconductor module 200 on the upper surface. This forms a space between the upper surface 10a of the wiring board 10 and a lower surface of each of the first semiconductor module 100 and the second semiconductor module 200.

In the spaces formed by the spacer 31 and the spacer 32, a controller 51 is provided. An integrated circuit that can control operations of the first semiconductor module 100 and the second semiconductor module 200 is incorporated into the controller 51. The controller 51 is connected to the conductive layer 17 via an electrode 53. This causes the controller 51 and the wiring board 10 to be electrically connected to each other.

As illustrated in FIG. 2A, the second semiconductor module 200 has a configuration in which the semiconductor chips 211 to 218 have been sequentially stacked from below. As described above, the semiconductor chips 211 to 218 have been stacked to shift in the negative Y direction as the semiconductor chip is located in a higher position. The semiconductor chips 211 to 218 are examples of a second semiconductor chip.

For example, the semiconductor chip 212 is arranged in a position that has slightly shifted in the negative Y direction when viewed from the semiconductor chip 211, on an upper surface of the semiconductor chip 211 in a lowermost layer. Furthermore, the semiconductor chip 213 is arranged in a position that has further shifted in the negative Y direction when viewed from the semiconductor chip 212, on an upper surface of the semiconductor chip 212.

However, the semiconductor chip 215 has a direction of shifting that is different from a direction of shifting of the semiconductor chip 214. Stated another way, the semiconductor chip 215 is arranged in a position that has shifted in the positive Y direction when viewed from the semiconductor chip 214, on an upper surface of the semiconductor chip 214. As a result of this, an end located on the positive Y direction side in the upper surface of the semiconductor chip 214 is covered with the semiconductor chip 215. Furthermore, arrangement in the position that has shifted in the positive Y direction causes a reduction in a distance between each of the semiconductor chip 215 and the semiconductor chips 216 to 218 that are stacked on the semiconductor chip 215, and the electrode 12. Therefore, a length of the wire W2 that connects each of the semiconductor chips 215 to 218 to the electrode 12 decreases. This results in improvements in electrical characteristics of the semiconductor device 1.

Note that in the present embodiment, an example where the semiconductor chip 215 has a direction of shifting that is different from the direction of shifting of the semiconductor chip 214 has been described, but this is not restrictive. In any semiconductor chip of the semiconductor chips 211 to 218, the direction of shifting may change.

Respective lower surfaces of the semiconductor chips 211 to 218 are provided with adhesive layers 241 to 248. The adhesive layers 241 to 248 are also called, for example, die attach films (DAFs), and are thermosetting resins molded in a film shape.

For example, among the adhesive layers 241 to 248, the adhesive layer 241 in a lowermost layer that is provided on a lower surface of the semiconductor chip 211 causes the semiconductor chip 211 to adhere to an upper surface of the spacer 32. Furthermore, the adhesive layer 242 in a second lowermost layer causes the semiconductor chip 212 to adhere to an upper surface of the semiconductor chip 211. As described above, the adhesive layers 242 to 248 are interposed between vertically adjacent semiconductor chips of the semiconductor chips 211 to 218, and cause the semiconductor chips 211 to 218 to adhere to each other.

Note that among the adhesive layers 241 to 248, the adhesive layer 245 that is provided on a lower surface of the semiconductor chip 215 has a layer thickness that is greater than layer thicknesses of the adhesive layers 241 to 244, 246, and 247. This aims to embed the wire 324 described later that extends from the electrode pad 224. Furthermore, the adhesive layer 248 in an uppermost layer that is provided on a lower surface of the semiconductor chip 218 also has a layer thickness that is greater than layer thicknesses of the adhesive layers 241 to 244, 246, and 247. This aims to embed the wire 315 described later that extends from an electrode pad 125. The thicknesses of the adhesive layers 245 and 248 are, for example, 20 um or more, and the thicknesses of the other adhesive layers are, for example, 10 um.

Ends located on the positive Y direction side in respective upper surfaces of the semiconductor chips 211 to 218 are provided with the electrode pads 221 to 228. The electrode pads 221 to 228 are respectively connected to wires 321 to 328. The wires 321 to 328 are examples of the wire W2 (FIG. 1).

Each of the wires 321 to 328 connects vertically adjacent electrode pads of the electrode pads 221 to 228 to each other, and connects any of the electrode pads 221 to 228 to the electrode 12. The wires 321 to 328 respectively extend upward from the electrode pads 221 to 228, are curved downward in a certain height position, and are connected to another electrode pad or the electrode 12. Each of the wires 321 to 328 has been formed by a wire bonding method.

For example, the wire 328 that extends from the electrode pad 228 is curved above the electrode pad 228, and is connected to the electrode pad 227 located below. As another example, the wire 327 that extends from the electrode pad 227 is curved above the electrode pad 227, and is connected to the electrode pad 226 located below. As yet another example, the wire 325 that extends from the electrode pad 225 is curved above the electrode pad 225, and is connected to the electrode 12.

Furthermore, for example, the wire 324 connects the electrode pad 224 to the electrode pad 223. At least part of the wire 324 has been embedded in the adhesive layer 245 that is provided on the lower surface of the semiconductor chip 215. This is because the end located on the positive Y direction side in the upper surface of the semiconductor chip 214 is covered with the semiconductor chip 215 due to a difference in the direction of shifting between the semiconductor chip 214 and the semiconductor chip 215. A diameter of the wire 324 is, for example, 18 um. Therefore, the wire 324 can be embedded in the adhesive layer 245 having, for example, a layer thickness of 20 um.

As illustrated in FIG. 2B, the first semiconductor module 100 has a configuration in which the semiconductor chips 111 to 118 have been sequentially stacked from below. As described above, the semiconductor chips 111 to 118 have been stacked to shift in the positive Y direction as the semiconductor chip is located in a higher position. The semiconductor chips 111 to 118 are examples of a first semiconductor chip.

Furthermore, the semiconductor chip 115 has a direction of shifting that is different from a direction of shifting of the semiconductor chip 114. Stated another way, the semiconductor chip 115 is arranged in a position that has shifted in the negative Y direction when viewed from the semiconductor chip 114, on an upper surface of the semiconductor chip 114. As a result of this, an end located on the negative Y direction side in the upper surface of the semiconductor chip 114 is covered with the semiconductor chip 115.

Note that here, eight semiconductor chips have been stacked, but the number of stacked semiconductor chips is not limited to this. For example, the first semiconductor module 100 may include a single semiconductor chip.

Lower surfaces of the semiconductor chips 111 to 118 are respectively provided with adhesive layers 141 to 148. The adhesive layers 141 to 148 are, for example, die attach films. Each of the adhesive layers 141 to 148 is interposed between vertically adjacent semiconductor chips of the semiconductor chips 111 to 118, and causes the semiconductor chips 111 to 118 to adhere to each other.

Note that among the adhesive layers 141 to 148, the adhesive layer 145 that is provided on a lower surface of the semiconductor chip 115 has a layer thickness that is greater than a layer thickness of another adhesive layer. This aims to embed the wire 314 described later that extends from the electrode pad 124.

Ends located on the negative Y direction side in upper surfaces 111a to 118a serving as first surfaces of the semiconductor chips 111 to 118 are provided with the electrode pads 121 to 128. The electrode pads 121 to 128 are respectively connected to wires 311 to 318. The wires 311 to 318 are examples of the wire W1 (FIG. 1).

Note that hereinafter, in some cases, in a case where the wires 311 to 318 do not need to be distinguished from each other, the wires 311 to 318 are collectively referred to as the wire W1, and in a case where the wires 321 to 328 do not need to be distinguished from each other, the wires 321 to 328 are collectively referred to as the wire W2.

Each of the wires 311 to 318 connects vertically adjacent electrode pads of the electrode pads 121 to 128 to each other, and connects any of the electrode pads 121 to 128 to the electrode 11. The wires 311 to 318 respectively extend upward from the electrode pads 121 to 128, are curved downward in a certain height position, and are connected to another electrode pad or the electrode 11. Each of the wires 311 to 318 has been formed by a wire bonding method.

For example, the wire 318 that extends from the electrode pad 128 is curved above the electrode pad 128, and is connected to the electrode pad 127 located below. As another example, the wire 317 that extends from the electrode pad 127 is curved above the electrode pad 127, and is connected to the electrode pad 126 located below.

As yet another example, the wire 315 that extends from the electrode pad 125 is curved above the electrode pad 125, and is connected to the electrode 11. A height position where the wire 315 is curved, that is, a height position of an upper end 315a of the wire 315, is roughly equal to a height position of the adhesive layer 248 of the second semiconductor module 200. The upper end 315a of the wire 315 is embedded in the adhesive layer 248, but the details will be described later.

The height position of the upper end 315a of the wire 315 is located above, for example, by 100 um, when viewed from the upper surface 115a of the semiconductor chip 115. The wire 315 is longer than another wire that connects one electrode pad of the electrode pads 121 to 128 to another electrode pad.

The first semiconductor module 100, the second semiconductor module 200, the wires 311 to 318, the wires 321 to 328, and the wiring board 10 are covered with a sealing member 500.

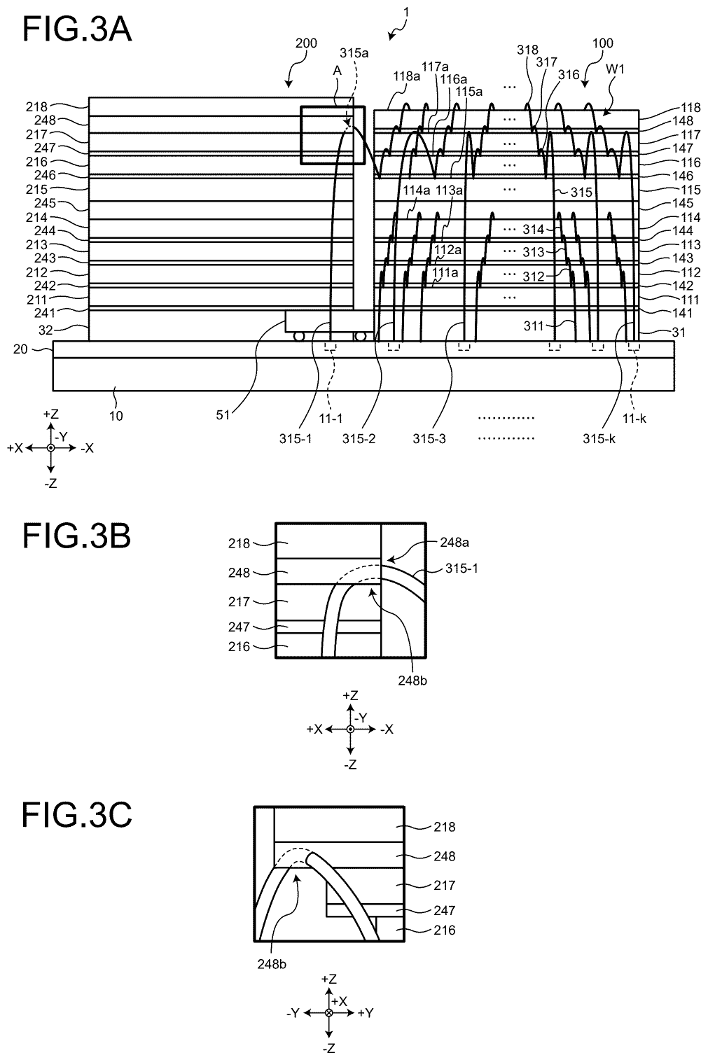

Next, a detailed configuration of the wires 311 to 318 that are respectively connected to the semiconductor chips 111 to 118 will be described with reference to FIGS. 3A to 3C.

FIGS. 3A to 3C are side views illustrating a detailed configuration of the semiconductor device 1 according to the embodiment. More specifically, FIG. 3A is a side view of the semiconductor device 1 when viewed from the negative Y direction side. Furthermore, FIG. 3B is a partially enlarged view of a frame line portion A of FIG. 3A, and FIG. 3C is a view of a configuration included in the frame line portion A of FIG. 3A when viewed from the negative X direction side. Note that in FIGS. 3A to 3C, illustration of some configurations such as the sealing member 500 is omitted.

As illustrated in FIG. 3A, respective pluralities of wires 311 to 318 extend from the upper surfaces 111a to 118a of the semiconductor chips 111 to 118. For example, from the upper surface 115a of the semiconductor chip 115, wires 315-1 to 315-k (k is an integer of 1 or more) extend as the wire 315. The wires 315-1 to 315-k are respectively connected to electrodes 11-1 to 11-k serving as the electrodes 11.

The respective wires 315-1 to 315-k are arranged in this order at predetermined intervals or more from an end located on the positive X direction side in the upper surface 115a of the semiconductor chip 115. Therefore, as illustrated in FIG. 3A, among the wires 315-1 to 315-k, the wire 315-1 that is arranged in a position closest to the second semiconductor module 200 extends to partially protrude to a side of the second semiconductor module 200 in some cases.

Meanwhile, in order to reduce the semiconductor device 1 in size, it has been desired that the first semiconductor module 100 and the second semiconductor module 200 be arranged on the wiring board 10 to be close to each other. However, if the first semiconductor module 100 and the second semiconductor module 200 are arranged to be close to each other, there is a possibility that part of the wire W1 that extends from the first semiconductor module 100 will interfere with the second semiconductor module 200. For example, in a case where the second semiconductor module 200 includes the semiconductor chips 211 to 218, as illustrated in FIG. 3A, if the wire W1 that extends from the first semiconductor module 100 interferes with a side surface of any of the semiconductor chips 211 to 218, a shirt circuit occurs between the first semiconductor module 100 and the second semiconductor module 200 in some cases.

Interference of the wire W1 with the second semiconductor module 200 can occur, for example, at the time of forming the wire W1 or at the time of sealing using the sealing member 500. This is because the wire W1 falls down at the time of forming the wire W1, or a position of the wire W1 deviates at the time of sealing in some cases. Falling down or deviation of the wire W1, as described above, more remarkably occurs as the wire W1 becomes longer.

Therefore, in the semiconductor device 1 according to the present embodiment, as illustrated in FIG. 3A, part of the wire W1 that extends from the first semiconductor module 100 is embedded in the adhesive layer of the second semiconductor module 200. Specifically, for example, part of the wire 315-1 that extends from the upper surface 115a of the semiconductor chip 115 is embedded in the adhesive layer 248 provided between the semiconductor chip 218 and the semiconductor chip 217 of the second semiconductor module 200.

More specifically, as illustrated in FIGS. 3B and 3C, the wire 315-1 is embedded in a portion that does not overlap the semiconductor chip 217 located just below in the adhesive layer 248. The wire 315-1 extends to penetrate between a side surface 248a of the adhesive layer 248 located on the negative X direction side and a portion that does not overlap the semiconductor chip 217 in a lower surface 248b of the adhesive layer 248.

As a result of the above, the wire 315-1 is supported by the adhesive layer 248, and this can prevent the wire 315-1 from falling down or deviating. Therefore, even in a case where the first semiconductor module 100 and the second semiconductor module 200 are arranged to be close to each other, the wire 315-1 can be prevented from interfering with the second semiconductor module 200. This can result in avoiding a shirt circuit between the first semiconductor module 100 and the second semiconductor module 200.

In the present embodiment, an example where the wire 315-1 is embedded in the adhesive layer 248 has been described, but the wire 315-1 is not necessarily embedded in the adhesive layer 248. It is sufficient if at least part of the wire 315-1 is in contact with the adhesive layer 248.

More specifically, for example, in the case of viewing a cross section including the lower surface 248b of the adhesive layer 248, part of the lower surface 248b may be recessed upward, and part of a cross section of the wire 315-1 may dig into a recessed portion. In other words, part of the cross section of the wire 315-1 may be fitted into a portion where part of the lower surface 248b is recessed. As another example, part of the lower surface 248b is not necessarily recessed. In the case of viewing the cross section including the lower surface 248b of the adhesive layer 248, it is sufficient if part of the lower surface 248b is in contact with part of the cross section of the wire 315-1. Embedding is an example of contact.

Note that, as described above, a layer thickness of the adhesive layer 248 is preferably, for example, 20 um or more, and is more preferably 40 um to 60 um. Furthermore, a diameter of the wire 315-1 is, for example, 18 um. Therefore, the wire 315-1 can be embedded in the adhesive layer 248.

### Method of Manufacturing Semiconductor Device

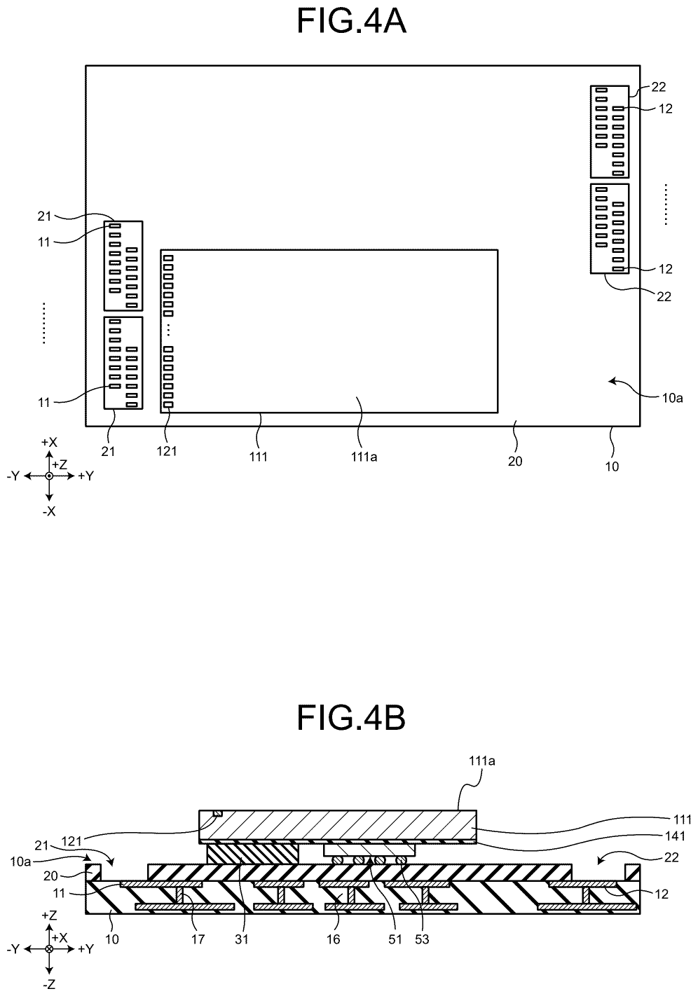

FIGS. 4A to 9B are diagrams illustrating an example of a procedure of a method of manufacturing the semiconductor device 1 according to the embodiment. More specifically, each of FIGS. 4A to 9A is a top view of the wiring board 10 when viewed from a positive Z direction side, and is a diagram that corresponds to FIG. 1. Furthermore, each of FIGS. 4B to 9B is a diagram illustrating cross sections taken along line AA and line BB of FIG. 1 in a superimposed manner, and is a diagram that corresponds to FIG. 2B. Note that in FIGS. 4B to 9B, in consideration of easiness of view, a configuration included in the second semiconductor module 200 is illustrated with a broken line, and hatching is partially omitted in some cases.

In FIGS. 4A and 4B, first, the plurality of electrodes 11 and the plurality of electrodes 12 are formed on the wiring board 10. Specifically, the plurality of electrodes 11 is formed in a position closer to the negative X direction side of an end located on the negative Y direction side in the wiring board 10, and the plurality of electrodes 12 is formed in a position closer to the positive X direction side of an end located on the positive Y direction side. Next, the wiring board 10 is covered with the solder resist 20, and the opening 21 and the opening 22 are formed in portions that overlap the plurality of electrodes 11 and the plurality of electrodes 12. As a result of this, the electrodes 11 and the electrodes 12 are exposed in the upper surface 10a of the wiring board 10.

Next, the semiconductor chip 111 is arranged on the upper surface 10a of the wiring board 10. At this time, the semiconductor chip 111 is arranged in such a way that the electrode pads 121 formed at an end located on the negative Y direction side in the upper surface 111a of the semiconductor chip 111 face the electrodes 11.

As illustrated in FIG. 4B, the adhesive layer 141 is provided on a lower surface of the semiconductor chip 111. The adhesive layer 141 adheres to an upper surface of the spacer 31.

Note that the controller 51 is connected to the upper surface 10a of the wiring board 10, before the semiconductor chip 111 is arranged.

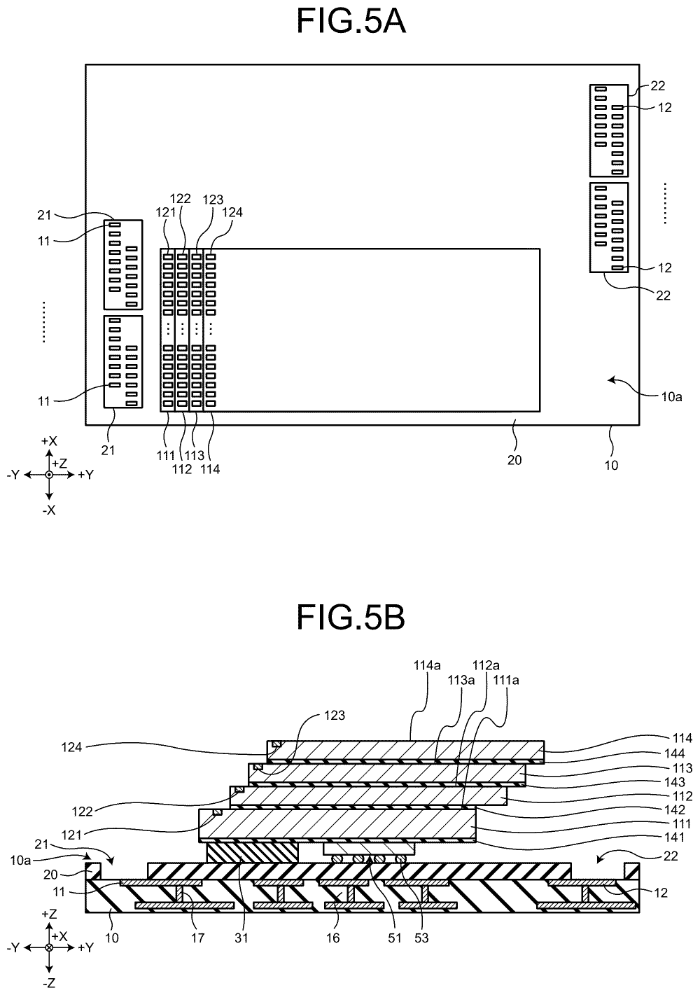

In FIGS. 5A and 5B, the semiconductor chips 112 to 114 in layers up to a fourth lowermost layer are stacked on the semiconductor chip 111. At this time, the semiconductor chips 112 to 114 are sequentially stacked to shift in the positive Y direction in such a way that the semiconductor chips 112 to 114 are not superimposed onto the electrode pads 121 to 123 formed at ends located on the negative Y direction side in the upper surfaces 111a to 113a of the semiconductor chips 111 to 113.

As illustrated in FIG. 5B, the semiconductor chips 111 to 114 are fixed to each other by using the respective adhesive layers 142 to 144 provided on lower surfaces of the semiconductor chips 112 to 114. By doing the above, a first lower module is formed. The first lower module is a portion including the semiconductor chips 111 to 114 in the first semiconductor module 100. The semiconductor chips 111 to 114 are semiconductor chips located on a lower layer side among the semiconductor chips 111 to 118.

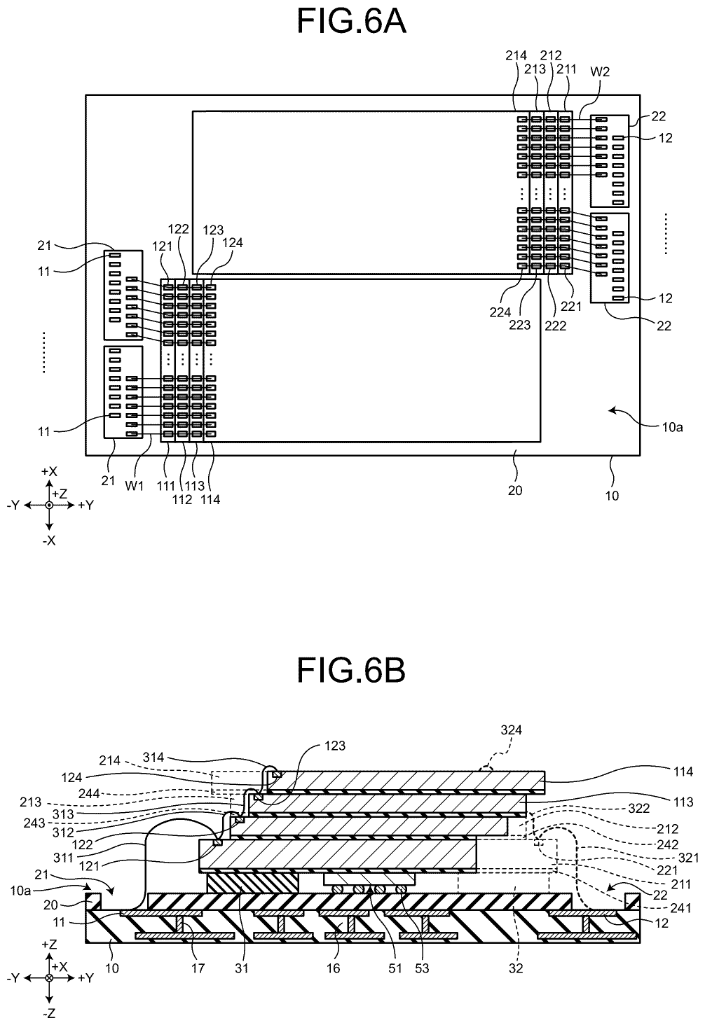

In FIGS. 6A and 6B, first, the semiconductor chip 211 is arranged in a position located on the positive X direction side when viewed from the semiconductor chips 111 to 114, on the upper surface 10a of the wiring board 10. At this time, the semiconductor chip 211 is arranged in such a way that the electrode pads 221 formed at an end located on the positive Y direction side in an upper surface of the semiconductor chip 211 face the plurality of electrodes 12 of the wiring board 10.

As illustrated in FIG. 6B, the adhesive layer 241 is provided on a lower surface of the semiconductor chip 211. The adhesive layer 241 adheres to an upper surface of the spacer 32.

Next, the semiconductor chips 212 to 214 in layers up to a fourth lowermost layer are stacked on the semiconductor chip 211. At this time, the semiconductor chips 212 to 214 are stacked to shift in the negative Y direction in such a way that the semiconductor chips 212 to 214 are not superimposed onto the electrode pads 221 to 223 formed at ends located on the positive Y direction side in upper surfaces of the semiconductor chips 211 to 213. The semiconductor chips 212 to 214 are fixed to each other by using the respective adhesive layers 242 to 244 provided on lower surfaces of the semiconductor chips 212 to 214. By doing the above, a second lower module is formed. The second lower module is a portion including the semiconductor chips 211 to 214 in a lowermost layer to the fourth lowest layer in the second semiconductor module 200.

Next, the wire bonding method is performed to form the wires 311 to 314 (W1) and the wires 321 to 324 (W2). This causes the semiconductor chips 111 to 114 and the semiconductor chips 211 to 214 to be electrically connected to the wiring board 10.

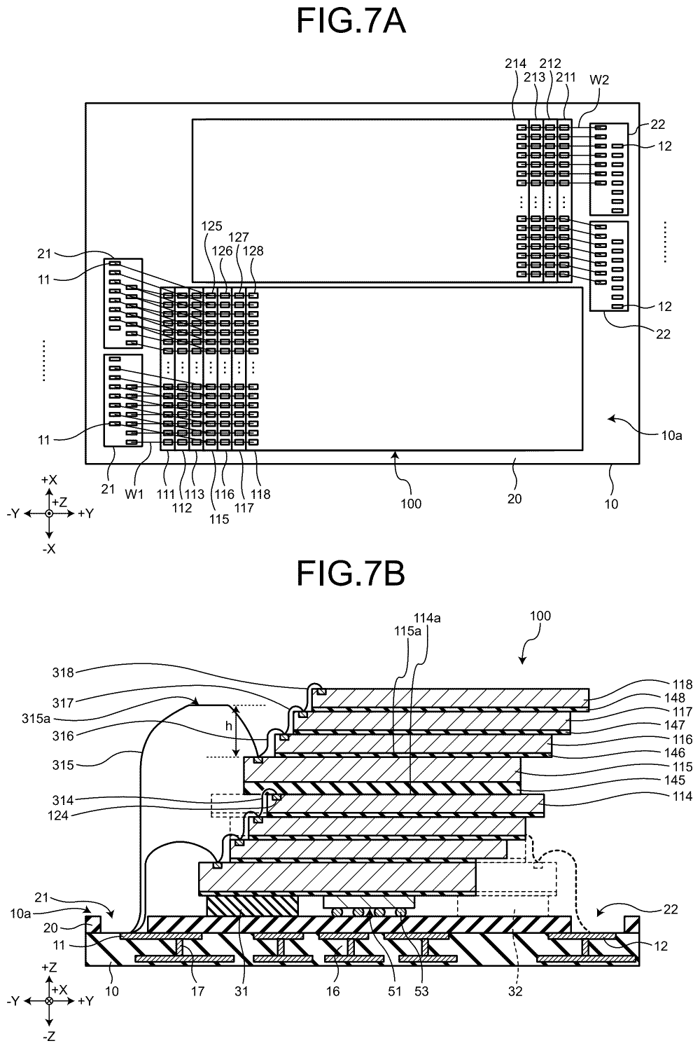

In FIGS. 7A and 7B, the semiconductor chips 115 to 118 are stacked on the semiconductor chip 114. Specifically, first, as illustrated in FIG. 7B, the semiconductor chip 115 is arranged in a position that has shifted in the negative Y direction when viewed from the semiconductor chip 114, on the upper surface 114a of the semiconductor chip 114. The semiconductor chip 115 is fixed to the semiconductor chip 114 by the adhesive layer 145 provided on the lower surface of the semiconductor chip 115. At this time, the wire 314 that extends from the electrode pad 124 is embedded in the adhesive layer 145.

Next, the semiconductor chips 116 to 118 are stacked on the semiconductor chip 115 to shift in the positive Y direction. As illustrated in FIG. 7B, the semiconductor chips 115 to 118 are fixed to each other by using the respective adhesive layers 146 to 148 provided on lower surfaces of the semiconductor chips 116 to 118. By doing the above, a first upper module is formed on the first lower module described above. The first upper module is a portion including the semiconductor chips 115 to 118 in the first semiconductor module 100. The semiconductor chips 115 to 118 are semiconductor chips located on an upper layer side among the semiconductor chips 111 to 118.

Next, as illustrated in FIG. 7B, the wire bonding method is performed to form the wires 315 to 318 (W1). This causes the first semiconductor module 100 to be electrically connected to the wiring board 10. The wires 315 to 318 (W1) are examples of a first wire.

Furthermore, in forming the wire 315, for example, the wire 315 extends upward from the upper surface 115a of the semiconductor chip 115, is curved downward in a position having height h from the upper surface 115a to form the upper end 315a, and is connected to the electrode 11. The height h is, for example, 100 um. As a result of this, when the adhesive layer 248 is formed later, a height position of the adhesive layer 248 is roughly equal to a height position of the upper end 315a of the wire 315.

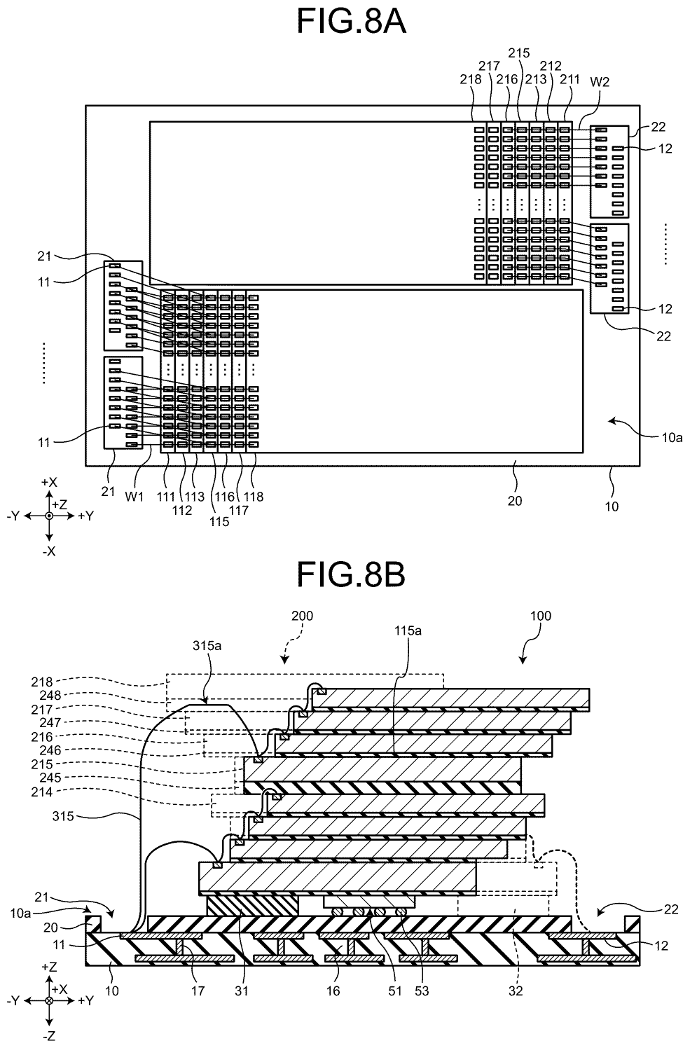

In FIGS. 8A and 8B, the semiconductor chips 215 to 218 are stacked on the semiconductor chip 214. Specifically, first, the semiconductor chip 215 is arranged in a position that has shifted in the positive Y direction when viewed from the semiconductor chip 214, on an upper surface of the semiconductor chip 214. The semiconductor chip 215 is fixed to the semiconductor chip 214 by the adhesive layer 245 provided on the lower surface of the semiconductor chip 215. At this time, the wire 324 that extends from the semiconductor chip 214 is embedded in the adhesive layer 245, but this is not illustrated.

Next, the semiconductor chips 216 and 217 are stacked on the semiconductor chip 215 to shift in the negative Y direction. The semiconductor chips 215 to 217 are fixed to each other by using the respective adhesive layers 246 and 247 provided on lower surfaces of the semiconductor chips 216 and 217.

Next, the semiconductor chip 218 is stacked on the semiconductor chip 217 to shift in the negative Y direction. At this time, the upper end 315a of the wire 315 (the wire 315-1 of FIG. 3A) that extends from the upper surface 115a of the semiconductor chip 115 is embedded in the adhesive layer 248 provided on the lower surface of the semiconductor chip 218. This causes the wire 315 to be supported by the adhesive layer 248. By doing the above, a second upper module is formed on the second lower module described above. The second upper module is a portion including the semiconductor chips 215 to 218 located upper than the lowermost to fourth lowermost layers in the second semiconductor module 200.

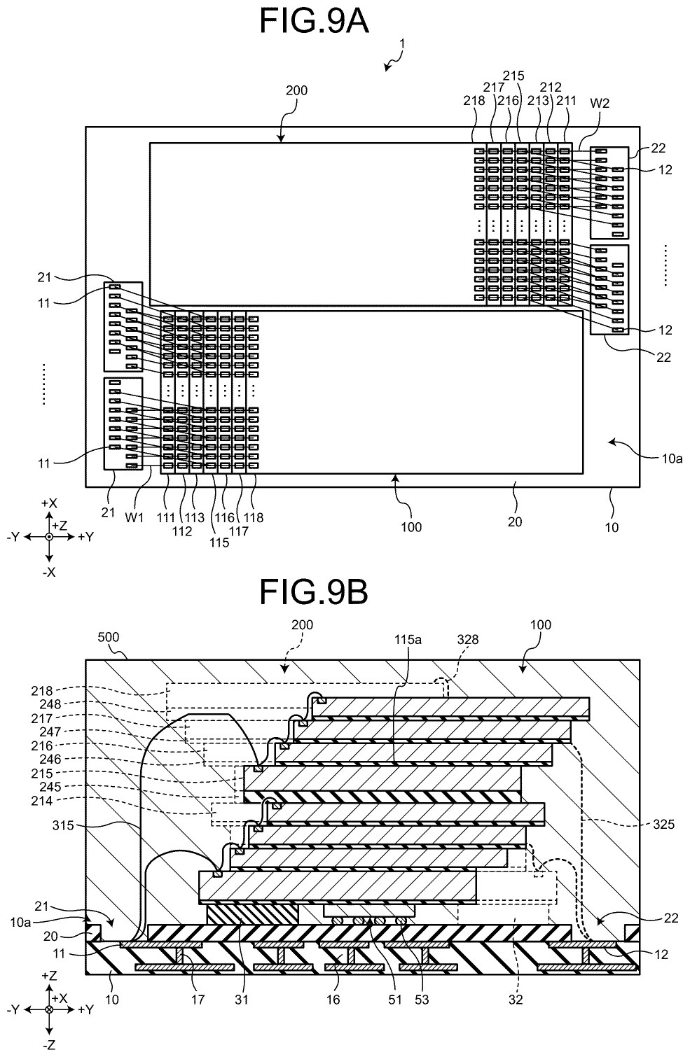

Next, as illustrated in FIG. 9B, the wire bonding method is performed to form the wires 325 to 328 (the wires W2). This causes the second semiconductor module 200 to be electrically connected to the wiring board 10. Note that in FIG. 9B, for convenience, illustration of the wires 326 and 327 is omitted.

Next, the wiring board 10, the first semiconductor module 100, the second semiconductor module 200, and the wires W1 and W2 are covered with the sealing member 500. Now, manufacturing of the semiconductor device 1 according to the embodiment has been completed.

### Overview

The semiconductor device 1 according to the embodiment includes the first semiconductor module 100 and the second semiconductor module 200 that are arranged to be adjacent to each other on the upper surface 10a of the wiring board 10. The first semiconductor module 100 has a configuration in which the semiconductor chips 111 to 118 have been stacked. At least one of the semiconductor chips 111 to 118 is connected to the wiring board 10 by the wire W1. The second semiconductor module 200 has a configuration in which the semiconductor chips 211 to 218 have been stacked. The second semiconductor module 200 includes the adhesive layer 248, for example, between the semiconductor chips 217 and 218 of the semiconductor chips 211 to 218. At least part of the wire W1 that extends from the first semiconductor module 100 is in contact with the adhesive layer 248 of the second semiconductor module 200.

This causes the wire W1 to be supported by the adhesive layer 248, and therefore the wire W1 can be prevented from interfering with the semiconductor chips 211 to 218. This can avoid a shirt circuit between the first semiconductor module 100 and the second semiconductor module 200.

Furthermore, by avoiding a short circuit between the first semiconductor module 100 and the second semiconductor module 200, a degree of freedom of arrangement positions of the first semiconductor module 100 and the second semiconductor module 200 is improved. For example, a distance between the first semiconductor module 100 and the second semiconductor module 200 can be reduced. This enables a further reduction in size of the semiconductor device 1.

### First Variation

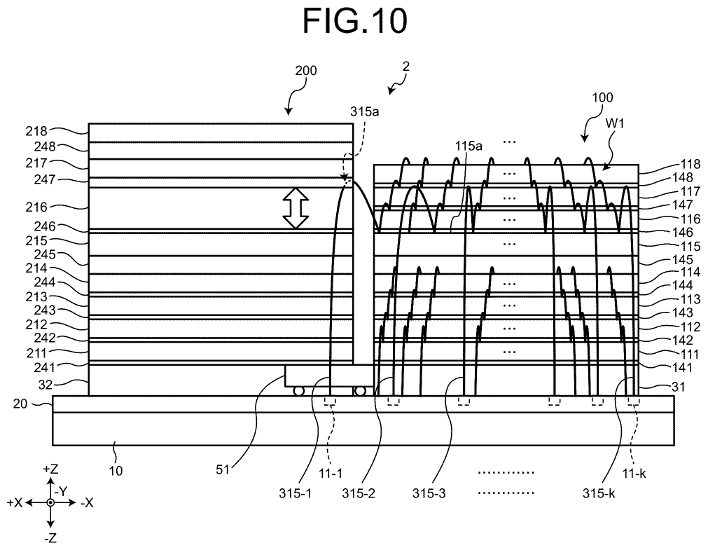

A first variation of the embodiment will be described with reference to FIG. 10.

In the embodiment described above, the wire 315-1 that extends from the first semiconductor module 100 is embedded in the adhesive layer 248 provided on the lower surface of the semiconductor chip 218 of the second semiconductor module 200. However, a portion into which the wire 315-1 is embedded is not limited to the adhesive layer 248. In the first variation, the portion into which the wire 315-1 is embedded is different from the portion in the embodiment described above. In the description below, a configuration that is similar to a configuration according to the embodiment described above is denoted by a similar reference sign, and the description thereof is omitted in some cases.

FIG. 10 is a diagram explaining a semiconductor device 2 according to the first variation of the embodiment. More specifically, FIG. 10 is a side view of the semiconductor device 2 according to the first variation when viewed from the negative Y direction side, and is a diagram that corresponds to FIG. 3A. Note that in FIG. 10, similarly, illustration of some configurations such as the sealing member 500 is omitted.

As illustrated in FIG. 10, in the semiconductor device 2 according to the first variation, among the semiconductor chips 211 to 218, for example, the semiconductor chip 216 has a layer thickness that is greater than a layer thickness of another semiconductor chip. Therefore, a height position of the adhesive layer 247 that is provided on a lower surface of the semiconductor chip 217 that has been stacked on the semiconductor chip 216 increases by an increase in layer thickness of the semiconductor chip 216. As a result of this, the height position of the adhesive layer 247 is roughly equal to a height position of the upper end 315a of the wire 315-1. This enables the wire 315-1 to be embedded in the adhesive layer 247 in contrast to the adhesive layer 248.

The semiconductor device 2 according to the first variation exhibits advantageous effects that are similar to advantageous effects of the semiconductor device 1 according to the embodiment described above.

### Second Variation

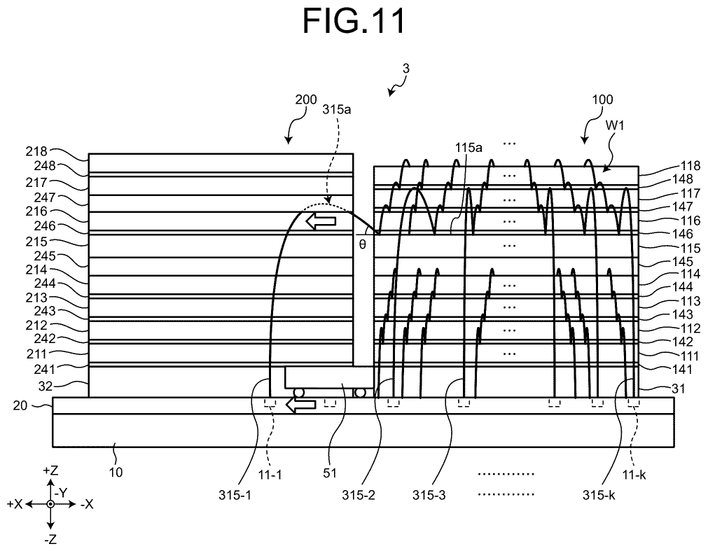

A second variation of the embodiment will be described with reference to FIG. 11.

In the first variation described above, a change in layer thickness of the semiconductor chip 216 causes a change in a portion into which the wire 315-1 is embedded. In contrast, in the second variation, an adhesive layer into which the wire 315-1 is embedded is changed according to a height position of the upper end 315a of the wire 315-1. In the description below, a configuration that is similar to a configuration of the embodiment described above or the first variation is denoted by a similar reference sign, and the description thereof is omitted in some cases.

FIG. 11 is a diagram explaining a semiconductor device 3 according to the second variation of the embodiment. More specifically, FIG. 11 is a side view of the semiconductor device 3 according to the second variation when viewed from the negative Y direction side, and is a diagram that corresponds to FIG. 10. Note that in FIG. 11, similarly, illustration of some configurations such as the sealing member is omitted.

As illustrated in FIG. 11, in the semiconductor device 3 according to the second variation, the height position of the upper end 315a of the wire 315-1 is lower. Furthermore, a layer thickness of the adhesive layer 247 is greater than layer thicknesses of the adhesive layers 241 to 244, 246, and 248. In the embodiment described above, as illustrated in FIG. 3A or the like, the wire 315-1 extends from the upper surface 115a of the semiconductor chip 115 in a direction forming, for example, 80 to 90 degrees relative to the upper surface 115a. In contrast, in the second variation, a position of the electrode 11-1 to which the wire 315-1 is connected has shifted in the positive X direction, as illustrated in FIG. 11. Therefore, as illustrated in FIG. 11, the wire 315-1 extends from the upper surface 115a of the semiconductor chip 115 in a direction forming an angle θ of, for example, 45 degrees relative to the upper surface 115a. This can lower the height position of the upper end 315a of the wire 315-1. As a result of this, the height position of the upper end 315a of the wire 315-1 is roughly equal to a height position of the adhesive layer 247. This enables the wire 315-1 to be embedded in the adhesive layer 247 in contrast to the adhesive layer 248. In other words, a layer thickness of any of the adhesive layers 241 to 248 that has a height position that is roughly equal to the height position of the upper end 315a of the wire 315-1 can be selectively increased in such a way that the wire 315-1 is embedded. For example, in a case where the height position of the upper end 315a of the wire 315-1 is roughly equal to a height position of the adhesive layer 246, the wire 315-1 may be embedded in the adhesive layer 246. In this case, a layer thickness of the adhesive layer 246 is greater than layer thicknesses of the adhesive layers 241 to 244, 247, and 248.

As described above, for example, even in a case where a position of the electrode 11-1 to which the wire 315-1 is connected has moved in the X direction in comparison with the first embodiment and the first variation, a portion into which the upper end 315a of the wire 315-1 is embedded can be adjusted. Stated another way, a layer thickness of any of the adhesive layers included in the second semiconductor module 200 can be increased according to the angle θ relative to the upper surface 115a or the height position of the upper end 315a of the wire 315-1 so that an adhesive layer having an increased layer thickness is selected as a portion into which the wire 315-1 is embedded.

The semiconductor device 3 according to the second variation exhibits advantageous effects that are similar to the advantageous effects of the semiconductor device 1 according to the embodiment described above.

Note that in the embodiment described above and the first and second variations, an example where the wire 315-1 is embedded in an arbitrary adhesive layer has been described, but this is not restrictive. An arbitrary wire W1 that extends from an arbitrary semiconductor chip of the semiconductor chips 111 to 118 may be embedded in an adhesive layer.

### Third Variation

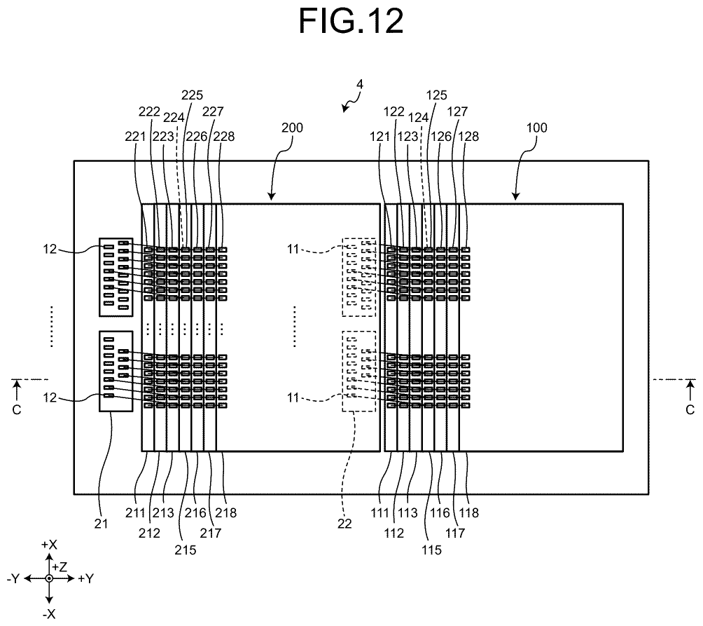

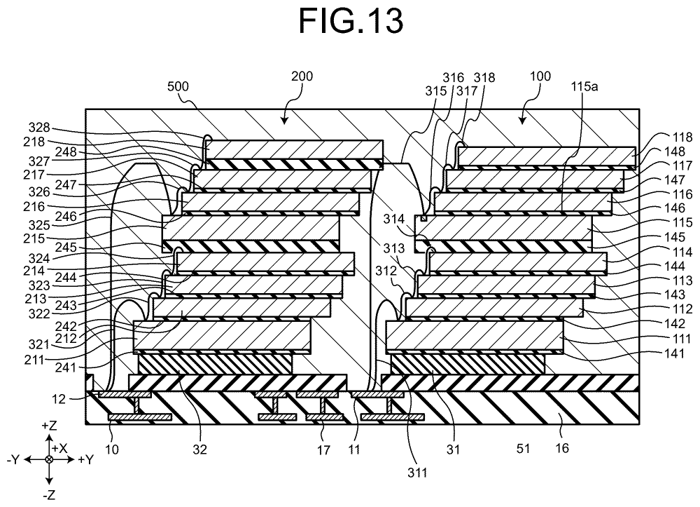

A third variation of the embodiment will be described with reference to FIGS. 12 and 13.

A semiconductor device 4 according to the third variation is different from the semiconductor device according to the embodiment described above in a direction of arrangement of the first semiconductor module 100 and the second semiconductor module 200. In the description below, a configuration that is similar to a configuration according to the embodiment described above is denoted by a similar reference sign, and the description thereof is omitted in some cases.

FIG. 12 is a top view illustrating a schematic configuration example of the semiconductor device 4 according to the third variation of the embodiment. More specifically, FIG. 12 is a diagram that corresponds to FIG. 1. Furthermore, FIG. 13 is a cross-sectional view illustrating a detailed configuration of the semiconductor device 4 according to the third variation of the embodiment. More specifically, FIG. 13 illustrates a cross section taken along line CC of FIG. 12.

As illustrated in FIGS. 12 and 13, on the upper surface 10a of the wiring board 10, the first semiconductor module 100 and the second semiconductor module 200 are arranged in the Y direction. Specifically, the first semiconductor module 100 is arranged on the positive Y direction side in the upper surface 10a of the wiring board 10, and the second semiconductor module 200 is arranged on the negative Y direction side when viewed from the first semiconductor module 100. Furthermore, the plurality of electrodes 11 is arranged on the negative Y direction side when viewed from the first semiconductor module 100, and the plurality of electrodes 12 is arranged in the negative Y direction side when viewed from the second semiconductor module 200.

Both the semiconductor chips 111 to 118 and the semiconductor chips 211 to 218 have been stacked to shift in the positive Y direction as the semiconductor chip is located in a higher position. Ends located on the negative Y direction side in the upper surfaces 111a to 118a serving as the first surfaces of the semiconductor chips 111 to 118, and the upper surfaces of the semiconductor chips 211 to 218 are provided with the electrode pads 121 to 128 and 221 to 228 (FIG. 12), and the electrode pads 121 to 128 and 221 to 228 are respectively connected to the wires 311 to 318 and 321 to 328 (FIG. 13). Each of the wires 311 to 318 and 321 to 328 extends in the negative Y direction, and is connected to the electrode 11 or the electrode 12.

As illustrated in FIG. 13, at least part of the wire 315 that extends from an end located on the negative Y direction side in the upper surface 115a of the semiconductor chip 115 is embedded in the adhesive layer 248 of the second semiconductor module 200. This causes the wire 315 to be supported by the adhesive layer 248.

The semiconductor device 4 according to the third embodiment exhibits advantageous effects that are similar to advantageous effects of the embodiment described above.

### Other Variations

In the embodiment and the variations that have been described above, for example, the adhesive layers 247 and 248 are provided on respective lower surfaces of the semiconductor chips 217 and 218, but this is not restrictive. For example, an adhesive layer may be provided on a side surface of each of the semiconductor chips 217 and 218, and the wire 315 may be embedded in the adhesive layer.

Furthermore, in the embodiment and the variations that have been described above, an example where a single wire 315 is embedded in the adhesive layer 248 has been described, but this is not restrictive. For example, a plurality of wires 315 may be embedded in the adhesive layer 248. Moreover, adhesive layers into which the plurality of wires is embedded may be different from each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a wiring board;
a first semiconductor module that is arranged on a principal surface of the wiring board, and includes one or more first semiconductor chips staked together;
a wire that connects one of the one or more first semiconductor chips to the wiring board; and
a second semiconductor module that is arranged on the principal surface of the wiring board to be adjacent to the first semiconductor module, and includes a plurality of second semiconductor chips stacked together, wherein
the second semiconductor module includes an adhesive layer between an N-th second semiconductor chip (N is an integer of 1 or more) and an (N+1)th second semiconductor chip from a lowermost layer among the plurality of second semiconductor chips, and
at least part of the wire is in contact with the adhesive layer.

2. The semiconductor device according to claim 1, wherein
the first semiconductor module includes a plurality of first semiconductor chips stacked together.

3. The semiconductor device according to claim 2, wherein
the wire extends from a first surface of one of the one or more first semiconductor chips, the first surface facing a stacked direction.

4. The semiconductor device according to claim 3, wherein
the plurality of first semiconductor chips is stacked to shift in a first direction along the principal surface,
the wire extends from an end in a second direction of the first surface of the one of the plurality of first semiconductor chips, the second direction being opposite to the first direction,
the plurality of second semiconductor chips is stacked to shift in the second direction, and
the first semiconductor module and the second semiconductor module are adjacent in a third direction along the principal surface, the third direction intersecting the first direction and the second direction.

5. The semiconductor device according to claim 3, wherein
the plurality of first semiconductor chips is stacked to shift in a first direction along the principal surface,
the wire extends from an end in a second direction of the first surface of the one of the plurality of first semiconductor chips, the second direction being opposite to the first direction,
the plurality of second semiconductor chips is stacked to shift in the first direction, and
the second semiconductor module is adjacent to the first semiconductor module in the second direction when viewed from the first semiconductor module.

6. The semiconductor device according to claim 4, wherein
the second semiconductor module includes a plurality of adhesive layers between the plurality of second semiconductor chips, the plurality of adhesive layers including the adhesive layer, and
among the plurality of adhesive layers, the adhesive layer has a layer thickness greater than a layer thickness of at least one of other adhesive layers.

7. The semiconductor device according to claim 4, wherein
at least the part of the wire is embedded in the adhesive layer.

8. The semiconductor device according to claim 1, wherein
a layer thickness of the adhesive layer is greater than a diameter of the wire.

9. The semiconductor device according to claim 1, wherein
the wire is formed by a wire bonding method.

10. The semiconductor device according to claim 1, further comprising:
a sealing member that covers the wiring board, the first semiconductor module, the second semiconductor module, and the wire.

11. The semiconductor device according to claim 1, wherein
the wire is in contact with a portion that does not overlap the (N+1)th second semiconductor chip in the adhesive layer.

12. The semiconductor device according to claim 4, wherein
the wire extends to penetrate between a side surface of the adhesive layer that intersects the third direction, and a portion that does not overlap the (N+1)th second semiconductor chip in a lower surface of the adhesive layer.

13. A method of manufacturing a semiconductor device, the method comprising:
forming a first semiconductor module on a principal surface of a wiring board, the first semiconductor module including one or more first semiconductor chips staked together;
forming a wire that connects each of the one or more first semiconductor chips to the wiring board; and
forming a second semiconductor module in a position adjacent to the first semiconductor module on the principal surface of the wiring board, the second semiconductor module including a plurality of second semiconductor chips stacked together, wherein
the forming the second semiconductor module includes:
forming an adhesive layer between an N-th second semiconductor chip (N is an integer of 1 or more) and an (N+1)th second semiconductor chip from a lowermost layer among the plurality of second semiconductor chips, and
bringing at least part of the wire into contact with the adhesive layer.

14. The method of manufacturing the semiconductor device according to claim 13, wherein
stacking of the one or more first semiconductor chips includes stacking a plurality of first semiconductor chips.

15. The method of manufacturing the semiconductor device according to claim 14, wherein
the forming the wire includes forming the wire that extends from a first surface of one of the one or more first semiconductor chips, the first surface facing a stacked direction.

16. The method of manufacturing the semiconductor device according to claim 13, wherein
the forming the first semiconductor module includes stacking a plurality of first semiconductor chips to shift in a first direction along the principal surface,
the forming the wire includes connecting the wire to an end in a second direction of a first surface of one of the plurality of first semiconductor chips, the first surface facing a stacked direction, the second direction being opposite to the first direction, and
the forming the second semiconductor module includes stacking the plurality of second semiconductor chips to shift in the second direction.

17. The method of manufacturing the semiconductor device according to claim 13, wherein
the forming the first semiconductor module includes stacking a plurality of first semiconductor chips to shift in a first direction along the principal surface,
the forming the wire includes connecting the wire to an end in a second direction of a first surface of one of the plurality of first semiconductor chips, the first surface facing a stacked direction, the second direction being opposite to the first direction, and
the forming the second semiconductor module includes stacking the plurality of second semiconductor chips to shift in the first direction.

18. The method of manufacturing the semiconductor device according to claim 16, wherein
the forming the adhesive layer includes forming a plurality of adhesive layers between the plurality of second semiconductor chips, the plurality of adhesive layers including the adhesive layer, and
among the plurality of adhesive layers, the adhesive layer has a layer thickness greater than a layer thickness of at least one of other adhesive layers.

19. The method of manufacturing the semiconductor device according to claim 16, wherein
the bringing at least the part of the wire into the adhesive layer includes embedding at least the part of the wire in the adhesive layer.

20. The method of manufacturing the semiconductor device according to claim 16, wherein
the first semiconductor module includes a first lower module and a first upper module, the first lower module including first semiconductor chips located on a lower layer side, the first upper module including first semiconductor chips located on an upper layer side among the plurality of first semiconductor chips,
the second semiconductor module includes a second lower module and a second upper module, the second lower module including second semiconductor chips from a lowermost layer to an L-th chip (L is an integer of 1 or more), L being smaller than N, the second upper module including second semiconductor chips that are upper than the L-th chip, among the plurality of second semiconductor chips,
the forming the first semiconductor module includes:
forming the first lower module on the principal surface; and
forming the first upper module on the first lower module, after forming the second lower module in a position adjacent to the first lower module on the principal surface,
the forming the wire includes forming a first wire that connects each of the first semiconductor chips included in the first upper module to the wiring board, and
the forming the second semiconductor module includes:
forming the second lower module in the position adjacent to the first lower module on the principal surface;
forming the second upper module on the second lower module, after forming the first wire;
forming the adhesive layer between the N-th second semiconductor chip and the (N+1)th second semiconductor chip from the lowermost layer among the second semiconductor chips included in the second upper module; and
bringing at least part of the first wire into contact with the adhesive layer.
